(19) United States
(12) Patent Application Publication
(10) Pub. No.: US 2008/0013275 A1
(43) Pub. Date: Jan. 17, 2008

(54) NETWORK EXPANSION ENCLOSURE

(75) Inventors: Ronald Wayne Beckley, Chambersburg, PA (US); Robert David Wright JR., Stigler, OK (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: APX Enclosures, Inc., Mercersburg, PA (US)

(21) Appl. No.: 11/755,858

(22) Filed: May 31, 2007

Related U.S. Application Data
(60) Provisional application No. 60/809,726, filed on May 31, 2006.

(51) Int. Cl. H05K 7/20; H02B 1/00; H05K 7/14

(52) U.S. Cl. 361/695; 361/600; 361/725

(57) ABSTRACT

An expansion enclosure assembly includes a bottom surface having apertures formed therein. The bottom surface may be adapted for connection with a base enclosure. The base enclosure includes a generator inlet connector aperture. The expansion enclosure includes cooling fans, racks for insertion of electronic components, access panels for enabling a user to access an interior of the enclosure, fiber optic cables suitable for installation through the generator inlet connector aperture, telephone cables suitable for installation through the generator inlet connector aperture, electrical cables suitable for installation through the generator inlet connector aperture, and a battery backup unit. The fiber optic cables, the telephone cables, and electrical cables of the expansion enclosure may be inserted through the generator inlet connector aperture during mounting of the expansion enclosure on the base enclosure. The cooling fans may draw air from the base enclosure and through the generator inlet connector aperture.

### CROSS REFERENCE TO RELATED APPLICATIONS

The subject matter disclosed herein claims priority under 35 U.S.C. § 119(e) to provisional U.S. Patent Application Ser. No. 60/809,726, filed May 31, 2006, entitled “NETWORK EXPANSION ENCLOSURE” which is hereby incorporated herein by reference in its entirety.

### FIELD OF THE INVENTION

The present invention relates generally to an enclosure for the storage of electronic components, and more particularly, for the storage of additional electronic components for a communications network.

### BACKGROUND OF THE INVENTION

Today, millions of Americans remain connected to the information super highway or Internet through their home computers. With greater software and networking capabilities, the increasing demand for more work output, and the increasing cost of transportation, many working adults are finding it easier to work from their home computers via an Internet connection.

In order to provide Internet access at home, Internet providers must run cable or Internet lines to individual homes. In order to convert signals originating from the fiber optic line of the service provider, enclosures such as an AFC 120, for example, are used. These enclosures provide the necessary circuitry to convert the signals coming from the fiber optic lines to a signal that can be transmitted over a copper connection into a typical home. Enclosures such as the AFC 120, while being rugged, may not, however, have additional rack space or cooling capacity for additional equipment.

With the increasing demand for higher Internet speeds, Internet service providers are now faced with the difficult issue of incorporating new technology into their current systems to provide a wider bandwidth. New technologies such as Asymmetric Digital Subscriber Lines (ADSL) and Digital Subscriber Lines (DSL) require more rack unit space for additional electronic components and cooling mechanisms. Current enclosures, such as the AFC 120 are already full with necessary components and cannot provide that necessary rack unit space.

One way to increase racking capacity would require workers to uninstall the current enclosures and reinstall a larger enclosure having more racking space and cooling abilities. Because the enclosure is in service, it cannot simply be turned off and replaced. This option, however, could become expensive since the larger enclosures require a new concrete foundation and a “hot switch over.”

Accordingly, there exists a need for an enclosure that extends the capacity and capabilities of the current network enclosures that will resolve the aforementioned drawbacks and deficiencies.

### SUMMARY OF THE INVENTION

The following summary provides an overview of various aspects of the invention. It is not intended to provide an exhaustive description of all of the important aspects of the invention, or to define the scope of the invention. Rather, this summary is intended to serve as an introduction to the detailed description and figures that follow.

In one aspect the expansion enclosure may include a bottom surface including at least an aperture formed therein. The bottom surface may be adapted for connection with a base enclosure. The base enclosure may be affixed to a pad. The base enclosure may include a generator inlet connector aperture. The expansion enclosure assembly may also include cooling fans, racks for insertion of electronic components, access panels for enabling user access to an interior of the enclosure, fiber optic cables suitable for installation through the generator inlet connector aperture, telephone cables suitable for installation through the generator inlet connector aperture, electrical cables suitable for installation through the generator inlet connector aperture, and a battery backup unit. The fiber optic cables, the telephone cables, and the electrical cables of the expansion enclosure may be inserted through the generator inlet connector aperture during mounting of the expansion enclosure on the base enclosure. The cooling fans may draw air through the base enclosure and through the generator inlet connector aperture.

Additional features and advantages of the invention will be made apparent from the following detailed description of illustrative embodiments.

### BRIEF DESCRIPTION OF THE DRAWINGS

The foregoing summary, as well as the following detailed description, is better understood when read in conjunction with the appended drawings. For the purpose of illustrating the invention, there is shown in the drawings exemplary constructions of the invention; however, the invention is not limited to the specific methods and instrumentalities disclosed. In the drawings:

FIG. 1 is an isometric view of an exemplary expansion enclosure in accordance with the present invention;

FIG. 2 is an isometric view of an exemplary expansion enclosure with the back panel open in accordance with the present invention;

FIG. 3 is a close-up view of a new exemplary generator inlet connector incorporated in the exemplary expansion enclosure in accordance with the present invention;

FIG. 4 is a close-up view of an exemplary DC power unit or module in accordance with the present invention;

FIG. 5 is a cut-out view of the exemplary expansion enclosure in accordance with the present invention;

FIG. 6 is an expanded view of an exemplary expansion enclosure and exemplary network base enclosure in accordance with the present invention;

FIG. 7 is an expanded view of an inverted exemplary expansion enclosure and an inverted network base enclosure in accordance with the present invention;

FIG. 8 is a front view of an exemplary expansion enclosure affixed to an exemplary network base enclosure in accordance with the present invention;

FIG. 9 is an isometric view of an exemplary expansion enclosure incorporated on top of an exemplary network base enclosure with front access panels and side access panels open in accordance with the present invention;

FIG. 10 is a side view of an exemplary expansion enclosure with front access panels and side access panels open in accordance with the present invention;

FIG. 11 is a side view of an exemplary expansion enclosure with the side access panel removed in accordance with the present invention;

FIG. 12 is a close-up view of the rear cover, the generator inlet cable, and the weather stripping to seal the cable routing aperture in accordance with the present invention;

FIG. 13 is a rear view of an exemplary expansion enclosure having only a single side portion and affixed to a network base enclosure in accordance with the present invention; and

FIG. 14 is an exemplary electrical circuit diagram of the electrical wiring of the exemplary expansion enclosure in accordance with the present invention.

### DETAILED DESCRIPTION OF ILLUSTRATIVE EMBODIMENTS

In the following, a detailed description of the present invention is given with reference to the drawings.

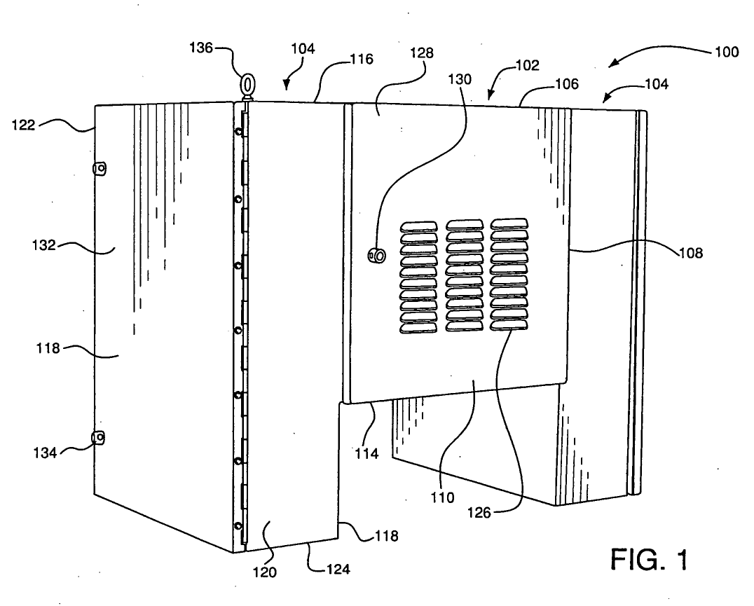

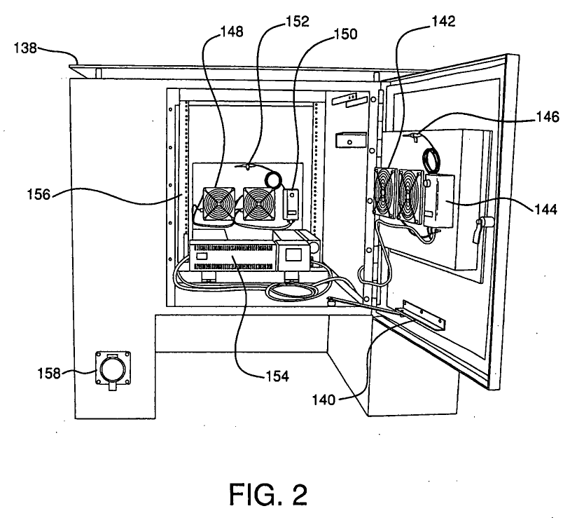

FIG. 1 is an isometric view of an exemplary expansion enclosure 100 in accordance with the present invention. The exemplary enclosure 100 may include a central portion 102 and two side or saddle portions 104. The central portion 102 may have a top surface 106, two side surfaces 108, a front surface 110, a back surface 112 (see FIG. 2), and a bottom surface 114. The central portion 102 may be in the shape of a cube, for example. The side or saddle portions 104 may also have a top surface 116, two side surfaces 118, a front surface 120, a back surface 122, and a bottom surface 124. The dimensions of the side portions 104 may vary from the central portion 102 such that the side portions 104 when attached to the central portion 102 may extend below the bottom surface 114 of the central portion 102, for example, as depicted in FIG. 1. In an alternative embodiment, the central portion 102 and side portions 104 may be integral. The dimensions of an exemplary expansion enclosure 100 may be 38 inches in height, 54 inches in width, and 28 inches in depth, for example.

The front surface 110 and the back surface 112 of the central portion 102 may include louvers 126 to assist in cooling. The front surface 110 and back surface 112 may also include access panels 128 for easy user access. The access panels 128 may also include handles 130 for easy access to the interior compartments of the expansion enclosure 100.

The side portions 104 may also include access panels 132 for easy access to the interior compartments of the expansion enclosure 100. The access panels 128 of the central portion 102 and the access panels 132 of the side portions 104 may include, for example, piano hinges or lift off hinges. Non-hinged lift off hardware, for example, may also be used in conjunction with the access panels 128 of the central portion 102 and the access panels 132 of the side portions 104 to permit full an unimpeded access to the expansion enclosure 100. The access panels 132 of the side portions 104 may also include handles 134 for opening. The access panels 128 and 132 may include Bell Core Quarter Turn Latches, for example. The top 106 of the central portion 102 or the top 116 of the side portions 104 may include lifting lugs 136 for increasing the maneuverability of the expansion enclosure 100. The expansion enclosure 100 may also include pad lockable hardware for security purposes.

The expansion enclosure 100 may be constructed of aluminum or steel for example. The expansion enclosure 100 may be constructed, for example, of aluminum with a polyester powder coating. A 0.125 5052 aluminum, for example, may be used to construct the expansion enclosure 100. The expansion enclosure 100 may include bolt on filter plenums and filters. The bolts may be composed of aluminum, for example.

FIG. 2 an isometric view of an exemplary expansion enclosure 100 with the back panel 128 open in accordance with the present invention. The expansion enclosure 100 may include a 3/16 inch solar shield 138, for example. The expansion enclosure 100 may also include a Door Restraint Bar System 140.

On the interior surface of the door 128, fans 142 may be positioned to provide cooling for the exemplary expansion enclosure 100. The fans 142 may be Alternating Current (AC) or Direct Current (DC) fans. The fans on the rear door 128 may be 48 VDC, 200 CFM fans, for example.

A thermostat 144 and a temperature sensing bulb 146 can be used, for example, to regulate the use of the fans 142 for cooling. The thermostat 144 may be a Johnson Controls A19-AAF-12 thermostat for example. As depicted in FIG. 2, a second set of fans 148, a second thermostat 150, and second temperature sensing bulb 152 may be positioned on the front door 128 for additional cooling. The fans 142 on the front door 128 may be 100 CFM fans, for example. The fans 142 on the front door 128 may also be 120 VAC, 200 CFM fans, for example. The expansion enclosure 100 may also include Model MX2A3 fans available from Comair Rotron, Inc., for additional cooling, for example. Use of the expansion enclosure 100 may eliminate the back pressure existing in the current network base enclosures 500. The existing fan 516 of the network base enclosure 500 may be augmented by, for example, a 400 CFM fan in the expansion enclosure 100. The fans in the expansion enclosure 100 will further assist in the cooling of the network base enclosure 500.

The expansion enclosure 100 may include a DC power unit or module 154 to provide power to the equipment in the expansion enclosure 100. The DC power unit or module 154 may be a 15 amp, 48 VDC power supply module with a 30 amp hour (AH) battery string to provide both a DC power supply and provide charging for the DC battery, for example. A second battery string may also be used. The expansion enclosure 100 may include a battery monitoring device and a 30 amp battery disconnect.

The expansion enclosure 100 may include equipment rack rails 156 for the securing new equipment, including electronic equipment, into the expansion enclosure 100. The equipment rack rails 156 may be extruded, for example. The equipment rack rails 156 may be 35 inches in length, for example, to provide additional rack unit space. The equipment rack rails 156 may also be 21 inches in length, for example. For example, the expansion enclosure 100 may include equipment rack rails 156 positioned for an additional 12 rack units in the central portion 102 and 8 rack units in the side portions 104 of the expansion enclosure 100 (1 rack unit=1.75 inches). The equipment rack rails 156 may be spaced 19, 23, or 24 inches apart, for example. The expansion enclosure 100 may also include horizontal rack angles for Pannaway Broadband Solutions, for example. The enclosure may also include additional shelving for additional storage.

The expansion enclosure 100 may also include an exemplary generator inlet connector 158. The generator inlet connector 158 allows users to connect external generators, for example, to the expansion enclosure 100 during extended power outages or to augment the power entering the expansion enclosure 100. The exemplary generator inlet connector 158 may be a 30 amp generator inlet receptacle, for example.

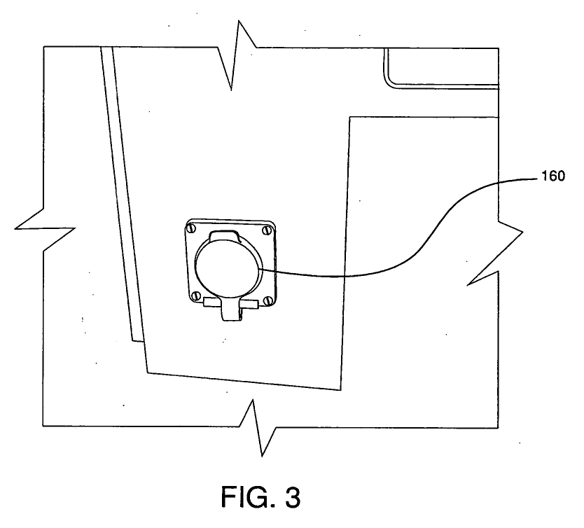

FIG. 3 is a close-up view of a new exemplary generator inlet connector 158 incorporated in the exemplary expansion enclosure 100 in accordance with the present invention. The new generator inlet connector 158 may include a cover 160, for example.

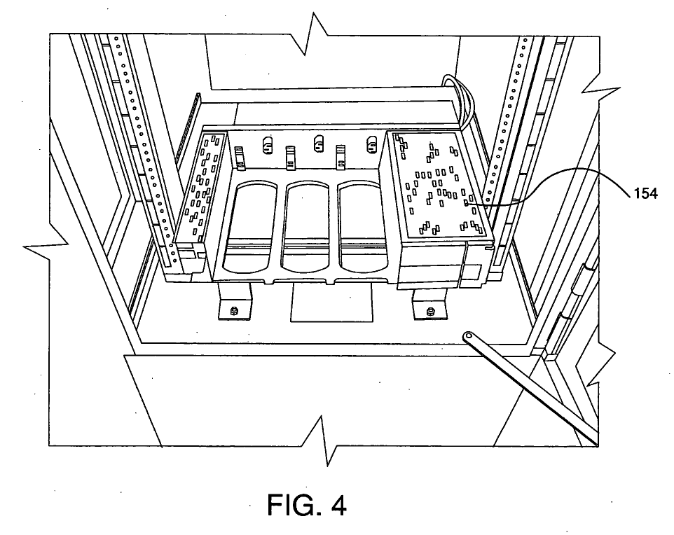

FIG. 4 is a close-up view of an exemplary DC power unit or module 154 in accordance with the present invention.

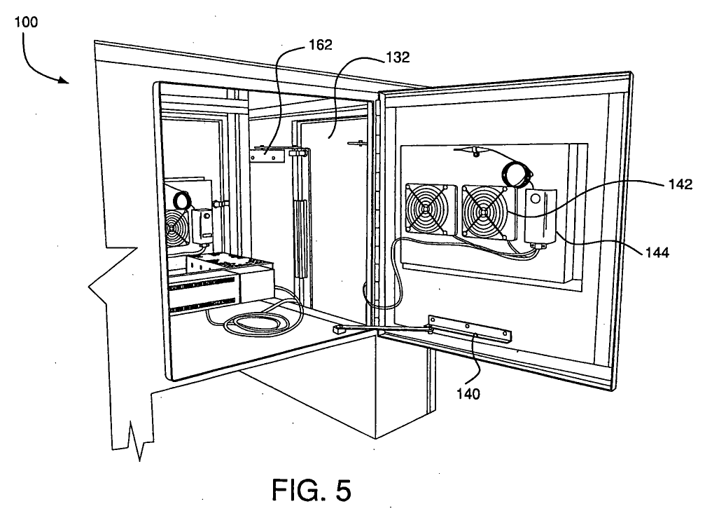

FIG. 5 is a cut-out view of the exemplary expansion enclosure 100 in accordance with the present invention. As depicted in FIG. 5, the side portions 104 may include additional side racks 162 for additional storage of equipment, including electronic equipment.

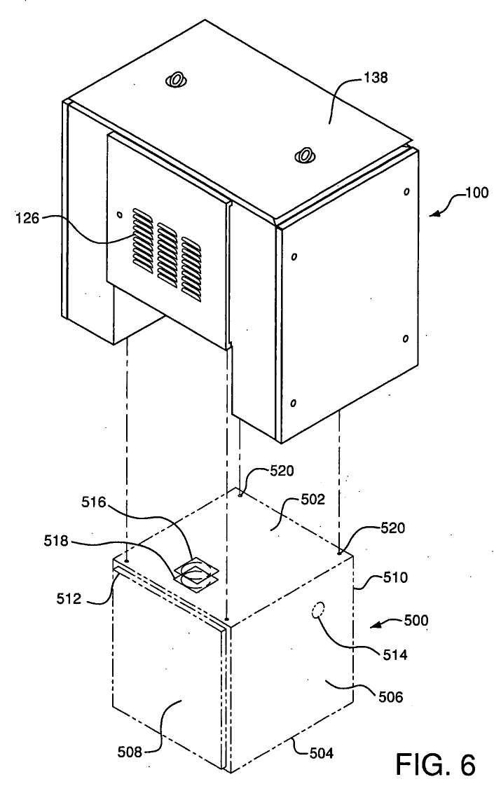

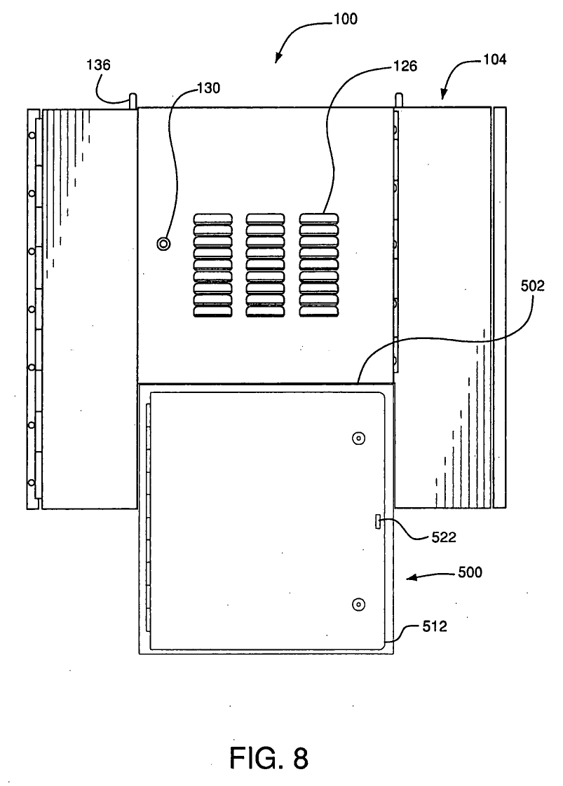

FIG. 6 is an expanded view of an exemplary expansion enclosure 100 and exemplary network base enclosure 500 in accordance with the present invention. The network base enclosure 500 may be an AFC 120 or AFC 240, for example. The network base enclosure 500 may be used to house telephone service equipment, for example. The network base enclosure 500 may include a top surface 502, a bottom surface 504, two side surfaces 506, a front surface 508, and a back surface 510. The network base enclosure 500 may include a front access panel 512 for access to its interior. The front access panel 512 on the network base enclosure 512 may also include handles 522 (see FIG. 8) for opening and a padlock assembly for security purposes. The network base enclosure 500 may be affixed to a concrete or cement pad in remote locations. The front access panel 512 may include hinges.

The base enclosure 500 may include a generator inlet connector assembly aperture 514 located on a side surface 506. An existing generator inlet connector assembly may be incorporated in the generator inlet connector assembly aperture 514. Where cost is an issue to the user, the existing generator inlet connector assembly may not be included and only the generator inlet connector assembly aperture 514 may be present. The base enclosure 500 may also include a fan assembly 516 and fan aperture 518 on the top surface 502.

Bolts, for example, may be used to mount the expansion enclosure 100 on to the network base enclosure 500. Existing sunshield mounting holes 520, for example, may allow for the expansion enclosure 100 to be secured directly on top of the network base enclosure 500 thereby precluding any required drilling.

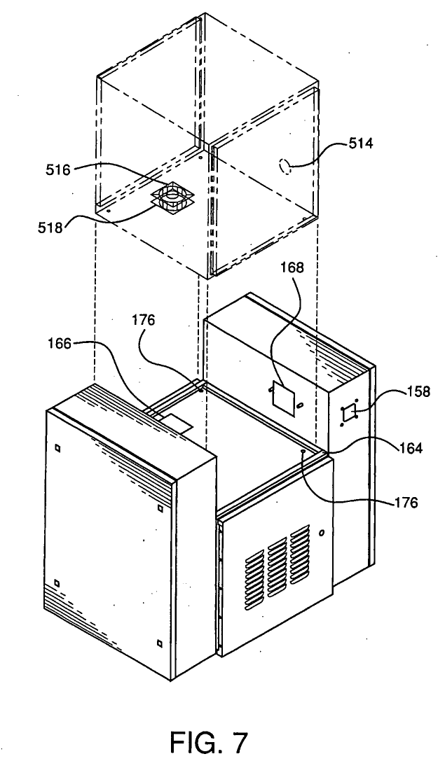

FIG. 7 is an expanded view of an inverted exemplary expansion enclosure 100 and an inverted network base enclosure 500 in accordance with the present invention. The expansion enclosure 100 may include a gasket or weather stripping 164 that provides a complete environmental seal with the existing network base enclosure 500 when the expansion enclosure 100 is affixed to the network base enclosure 500. The gasket or weather stripping 164 may be composed of rubber, for example. The expansion enclosure 100 may eliminate approximately 50% of the solar load of the network base enclosure 500, for example. The expansion enclosure 100 may also include mounting holes 176 for securing the expansion enclosure 100 to the network base enclosure 500.

The expansion enclosure 100 may include a fan aperture 166 and cable routing aperture 168. The fan aperture 166 may be positioned proximate to the fan aperture 518 of the network base enclosure 500 so that fluid communication is established between the network base enclosure 500 and the expansion enclosure 100. The cable routing aperture 168 may be positioned proximate to the generator inlet connector assembly aperture 514 such that when the expansion enclosure 100 is affixed to the network base enclosure 500, fluid communication is established between the cable routing aperture 168 and the generator inlet connector assembly aperture 514. In order to supplement the capabilities of the network base enclosure 500 with the least amount of physical modifications, it is envisioned that the generator inlet connector assembly, if present, be removed from the network base enclosure 500 to allow for cabling to enter the network base enclosure 500 though the generator inlet connector assembly aperture 514. Some network base enclosures 500 may not include a generator inlet connector assembly, but may only include the generator inlet connector assembly aperture. The expansion enclosure 100 may, however, have the capability of relocating the generator inlet connector assembly in the expansion enclosure. The cabling for the base enclosure 500 may include fiber optic cables, telephone cables, and electrical cables that may be fed through the generator inlet connector assembly aperture 514 of the network base enclosure 500. The fiber optic cables, telephone cables, and electrical cables may be used to connect the components of the network base enclosure 500 to the expansion enclosure 100 or directly to the network.

FIG. 8 is a front view of an exemplary expansion enclosure 100 affixed to an exemplary network base enclosure 500 in accordance with the present invention. As depicted in FIG. 8, the side portions of the expansion enclosure 100 may extend beyond the top surface 502 of the of the network base enclosure 500.

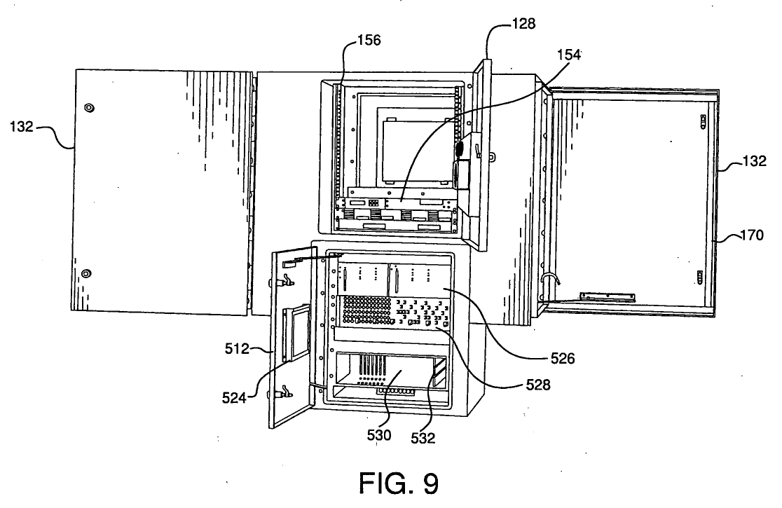

FIG. 9 is an isometric view of an exemplary expansion enclosure 100 incorporated on top of an exemplary network base enclosure 500 with front access panels 128 and 512 and side access panels 132 open. The network base enclosure 500 may include a print pocket 524 for safe guarding of owner's manuals and other important paperwork. The network base enclosure 500 may include an existing DC power module 526 and an existing network protection module 528 that provides protection from power surges. The network base enclosure 500 may also include existing network equipment 530, including PC Boards 532.

A gasket or weather seal 170 may be used in conjunction with the side access panels 132 to complete an environmental seal between side access panels 132 and the side surfaces 118 of the side portion 104. The gasket may be composed of rubber, for example.

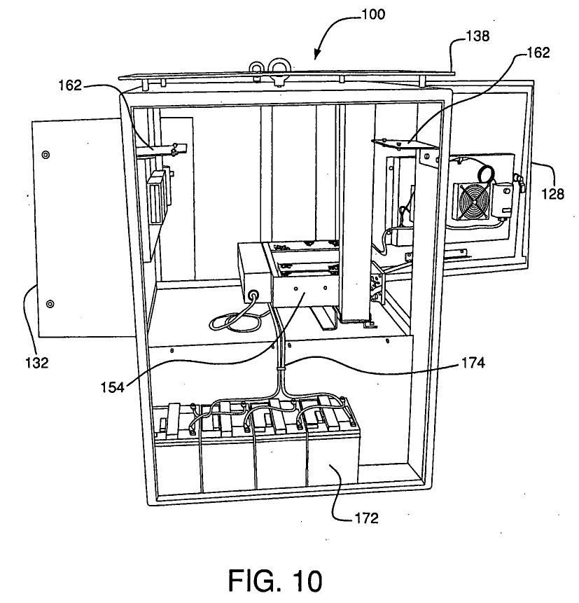

FIG. 10 is a side view of an exemplary expansion enclosure 100 with front access panels 128 and side access panels 132 open. The batteries 172 of the expansion enclosure 100 may be 12 volt, 30 AH, Valve Regulated Lead Acid (VRLA) batteries. The batteries 172 may also be 30 AH C&D Tel 12-30 batteries. The batteries may be stored in the side portions 104 of the expansion enclosure 100, for example, or the central portion 102. The batteries 172 may be connected to the DC Power module 154 with battery cables 174, for example.

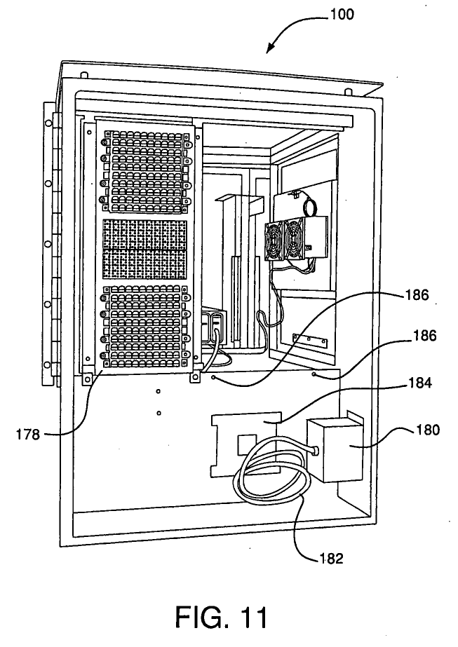

FIG. 11 is a side view of an exemplary expansion enclosure 100 with the side access panel 132 removed. The expansion enclosure 100 may include a network protection module or protector block 178 to safeguard against power surges. The network protection module 178 may be a 100 Pair Protector Block with Rocker Style connectors, for example. The enclosure may also include apertures 186 for inclusion of a second network protection module and grounding, for example. The network protection module 178 may be located in the side portions 104 of the expansion enclosure 100, for example, or in the central portion 102. The expansion enclosure 100 may include a rear cover 180 for the generator inlet connector 158 and the corresponding generator inlet cable 182. The expansion enclosure 100 may also include weather stripping 184 to seal the cable routing aperture 168.

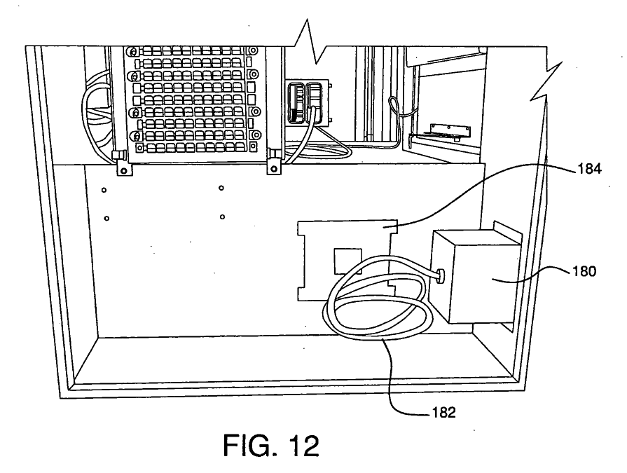

FIG. 12 is a close-up view of the rear cover 180, the generator inlet cable 182, and the weather stripping 184 to seal the cable routing aperture 168.

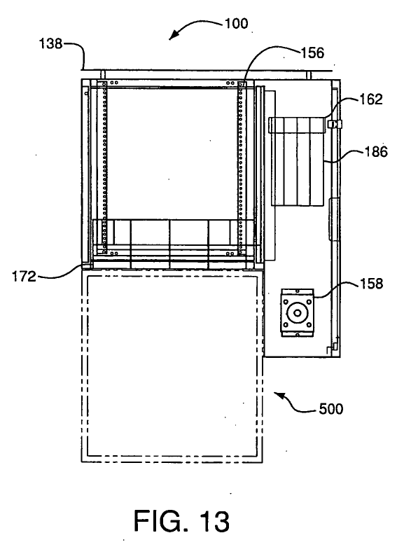

FIG. 13 is a rear view of an exemplary expansion enclosure 100 having only a single side portion 104 and affixed to a network base enclosure 500 in accordance with the present invention. The batteries 172 in this configuration are positioned in the central portion 102 of the expansion enclosure 100. As depicted in FIG. 13, new electronic equipment 186 can be organized and hang from the additional side racks 162.

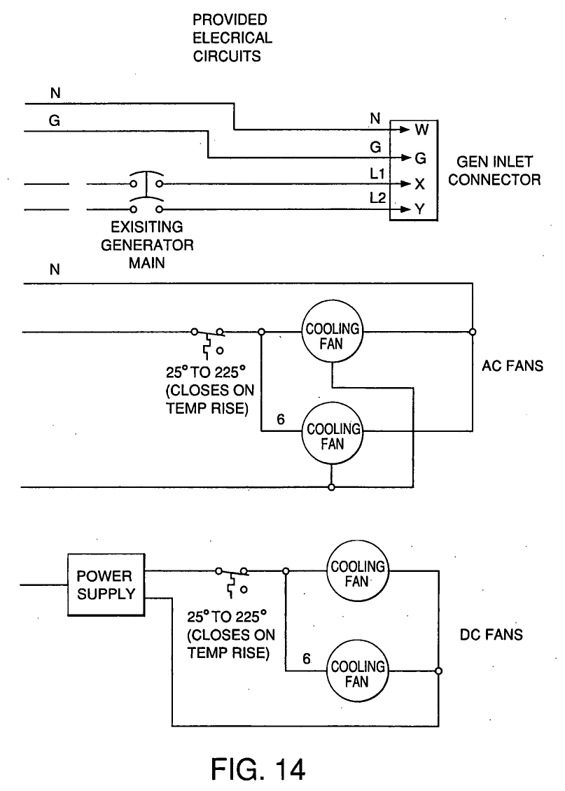

FIG. 14 is an exemplary electrical circuit diagram of the electrical wiring of the exemplary expansion enclosure 100 in accordance with the present invention. The exemplary electrical circuit diagram shows the wiring of two AC cooling fans and two DC cooling fans with their respective thermostats. FIG. 14 also depicts the generator connector and an exemplary power supply wiring.

It is noted that the foregoing examples have been provided merely for the purpose of explanation and are in no way to be construed as limiting of the present invention. For example, several of the figures, including FIG. 2, depict the expansion enclosure 100 having two side portions 104 that extend beyond the top surface 502 of the network base enclosure 500. These side portions 104 of the expansion enclosure 100, may be removable allowing the expansion enclosure 100 to be used in areas where expansion space is limited. While the invention has been described with reference to various embodiments, it is understood that the words which have been used herein are words of description and illustration, rather than words of limitations. Further, although the invention has been described herein with reference to particular means, materials and embodiments, the invention is not intended to be limited to the particulars disclosed herein; rather, the invention extends to all functionally equivalent structures, methods and uses, such as are within the scope of the appended claims.

What is claimed:

1. An expansion enclosure assembly for use with a base enclosure, said base enclosure being affixed to a pad and having a generator inlet connector aperture, said expansion enclosure comprising:
a bottom surface comprising at least an aperture formed therein, said bottom surface is adapted for connection with said base enclosure;
cooling fans;
racks for insertion of electronic components;
access panels for enabling access to an interior of the enclosure;
fiber optic cables suitable for installation through the generator inlet connector aperture;
telephone cables suitable for installation through the generator inlet connector aperture;
electrical cables suitable for installation through the generator inlet connector aperture; and
a battery backup unit,
whereby the fiber optic cables, the telephone cables, and the electrical cables of the expansion enclosure are inserted through the generator inlet connector aperture during mounting of the expansion enclosure on the base enclosure, and whereby the cooling fans draw air from the base enclosure and through the generator inlet connector aperture.

2. The expansion enclosure assembly of claim 1, wherein the expansion enclosure assembly is constructed of aluminum.

3. The expansion enclosure assembly of claim 2, wherein the expansion enclosure assembly is constructed of aluminum with a polyester powder coating.

4. The expansion enclosure assembly of claim 1, wherein the base is an AFC 120.

5. The expansion enclosure assembly of claim 1, further comprising a gasket located between said expansion enclosure and said base enclosure.

6. The expansion enclosure assembly of claim 5, wherein the gasket is composed of rubber.

7. The expansion enclosure assembly of claim 1, wherein the battery backup unit comprises a 15 amp, 48 VDC power supply with a 30 amp hour battery string.

8. The expansion enclosure assembly of claim 1, further comprising a battery monitoring device.

9. The expansion enclosure assembly of claim 1, wherein said cooling fans are located on a front portion and a rear portion of the expansion enclosure.

10. A method for affixing an expansion enclosure on to a base enclosure, comprising:
connecting a cable of the expansion enclosure to the base enclosure through the generator inlet connector assembly aperture; and
mounting the expansion enclosure to the base enclosure.

11. The method of claim 10, wherein the cable is a fiber optic cable.

12. The method of claim 10, wherein the cable is a telephone cable.

13. The method of claim 10, wherein the cable is an electrical cable.

14. The method of claim 10, further comprising removing a generator inlet connector assembly.

15. The method of claim 10, further comprising securing the expansion enclosure to the base enclosure with bolts through a set of sunshield mounting holes in the base enclosure.

16. An expansion enclosure for mounting on to a base enclosure, comprising:
a top portion, a bottom portion, a front portion, a rear portion, and two side portions, the bottom portion including at least an aperture formed therein,
a pair of rack rails for storage of electronic components;
an access panel to allow a user to access an interior of the enclosure;
a battery backup unit; and
a cooling system comprising cooling fans, whereby the cooling fans draw air from the base enclosure and through the generator inlet connector aperture.

17. The expansion enclosure assembly of claim 16, wherein the expansion enclosure assembly is constructed of aluminum.

18. The expansion enclosure assembly of claim 16, further comprising a battery monitoring device.

19. The expansion enclosure assembly of claim 16, wherein said cooling fans are located on the front portion and the rear portion of the expansion enclosure.

20. The expansion enclosure assembly of claim 16, further comprising cabling to connect the components of the base enclosure to the expansion enclosure.
